(19) United States
(12) Patent Application Publication
(10) Pub. No.: US 2016/0334701 A1
(43) Pub. Date: Nov. 17, 2016

(54) PHOTOCURABLE COMPOSITION FOR NANOIMPRINTING, AND METHOD FOR FORMING FINE PATTERN USING THE SAME

(71) Applicant: DAICEL CORPORATION, Osaka-shi, Osaka (JP)

(72) Inventors: Takeshi FUJIKAWA, Himeji-shi (JP); Takuya YAMAMOTO, Himeji-shi (JP)

(73) Assignee: DAICEL CORPORATION, Osaka-shi, Osaka (JP)

(21) Appl. No.: 15/111,552

(22) PCT Filed: Jan. 6, 2015
(86) PCT No.: PCT/JP2015/050132

§ 371 Date: Jul. 14, 2016

(30) Foreign Application Priority Data
Jan. 29, 2014 (JP) 2014-013994

(51) Int. Cl. G03F 7/00; H01L 33/00; G03F 7/004

(52) U.S. Cl. CPC G03F 7/0002; G03F 7/0048; H01L 33/0075

(57) ABSTRACT

Provided is a photocurable composition that is used for nanoimprinting and can give, on a wafer, a uniform thin film that maintains a uniform thickness without causing uneven resin distribution even after being left stand for a certain time and still enables transfer of, and formation of, a fine pattern with good precision from a mold onto the thin film. The photocurable composition for nanoimprinting includes components (A), (B), (C), and (D) and includes the component (C) in a content of 1 to 30 weight percent based on the total amount (100 weight percent) of the photocurable composition. The component (A) is a cationically curable compound represented by Formula (1). The component (B) is a cationic photoinitiator. The component (C) is a hydroxy-containing solvent having a boiling point of 100° C. to 210° C. (at 760 mmHg). The component (D) is a solvent that is devoid of hydroxy, has a boiling point of 140° C. to 210° C. (at 760 mmHg), and has monomer solubility in terms of solubility parameter of 8.0 to 10.0 (cal/cm³)^{1/2}.

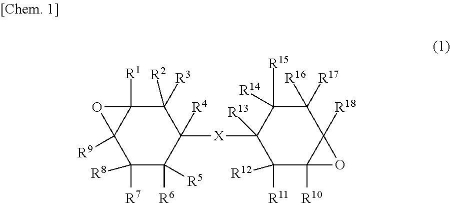

### TECHNICAL FIELD

The present invention relates to photocurable compositions for nanoimprinting; and to methods for forming fine patterns using the photocurable compositions. The photocurable compositions are used typically as or in radiation-sensitive resins, liquid crystal resist materials, coating materials, coating compositions, and adhesives. The radiation-sensitive resins are used as or in materials for lithography using active radiations such as far-ultraviolet rays, electron beams, ion beams, and X rays in semiconductor processes; and for the formation of insulating films, protective films, and any other components to be provided in electronic components such as liquid crystal display devices, integrated circuit devices, and solid-state imagers. The liquid crystal resist materials are used for the formation of liquid crystal display materials such as liquid crystal display photospacers, liquid crystal display rib-forming materials, over coatings, color resists for color filter formation, and TFT insulating films. This application claims priority to Japanese Patent Application No. 2014-013994 filed to Japan Jan. 29, 2014, the entire contents of which are incorporated herein by reference.

### BACKGROUND ART

Light-emitting diodes (LEDs) have excellent energy conversion efficiency, are long lasting, and are widely used typically in electronic appliances. The LEDs each have a structure including a substrate of inorganic material (inorganic substrate), and a light-emitting layer (light-emitting layer) of GaN semiconductor disposed on the substrate. Disadvantageously, however, there are large differences in refractive index between the inorganic substrate and the GaN semiconductor and between the inorganic substrate and the air (atmosphere). Owing to this, most of the total amount of light generated in the light-emitting layer repeatedly reflects within the layer and disappears. This causes the LEDs to have poor light-extraction efficiency.

A possible, known technique to solve the problem is a technique of forming a fine pattern of about several micrometers on an inorganic substrate, and disposing a GaN semiconductor light-emitting layer on the fine pattern.

With a conventional technique to form a fine pattern, the fine pattern is formed by forming a mask on the inorganic substrate via photolithography, and etching the inorganic substrate using the mask. Disadvantageously, however, cost and processing time increase with an increasing size of the inorganic substrate and/or with a decreasing size of the pattern (to be at nanopattern level). Under these circumstances, a technique of forming the mask not via photolithography, but via nanoimprinting has received attention.

In general, such a thin film is formed on an inorganic substrate typically by techniques of forming the thin film via screen process printing or using a bar coater. These techniques, however, are disadvantageous from the viewpoints of industrial productivity and film uniformity. Specifically, it is difficult to form the thin film with good precision in a simple manner according to these techniques. In contrast, spin coating enables easy preparation of the thin film. Disadvantageously, however, the spin coating may cause the substrate to have lowered surface smoothness. Specifically, for example, it is difficult, from the viewpoint of handling, to continuously prepare films having uniform thicknesses via the spin coating, or the spin coating causes narrow lines or bands (streaks; wrinkles), which are called “striation”. This problem has been solved by specifying conditions for the process (Patent Literature (PTL) 1 and PTL 2). These techniques, however, disadvantageously require more complicated conditions and more complicated operations.

Independently, a known photocurable composition for use in nanoimprinting employs radically polymerizable compounds such as vinyl ethers having an aliphatic ring structure, and vinyl ethers having both an aliphatic cyclic structure and an aromatic cyclic structure (PTL 3). However, the radically polymerizable compounds undergo large cure shrinkage and hardly give a fine pattern with good precision. Such photocurable compositions are required to be rapidly cured after application onto the substrate to form a thin film. Disadvantageously, however, the radically polymerizable compounds undergo polymerization inhibition by oxygen to have a lower curing rate and to have lower curability, in particular, in a thin film. A possible solution to the polymerization inhibition by oxygen is a technique of curing the composition in an atmosphere of nitrogen or another inert gas. Disadvantageously, however, this technique requires large-scale facilities and suffers from, for example, lower working efficiency because it takes a long tome to replace the atmosphere (air) with the inert gas.

### CITATION LIST

### Patent Literature

PTL 1: Japanese Unexamined Patent Application Publication (JP-A) No. 2002-246293

PTL 2: Japanese Patent No. 3109800

PTL 3: JP-A No. 2011-157482

### SUMMARY OF INVENTION

### Technical Problem

Solvents for use in photocurable compositions for nanoimprinting are generally selected typically from ether solvents, ester solvents, ketone solvents, amide solvents, and hydrocarbon solvents. With these solvents, however, it is difficult to control the solvent volatilization rate upon thin film preparation typically by spin coating. When the resulting thin film is left stand for a certain time, the uncontrollability of the solvent volatilization rate causes a component resin in the thin film to distribute unevenly, and the thin film may hardly maintain its uniform thickness.

Accordingly, the present invention has an object to provide a photocurable composition for nanoimprinting as follows. The photocurable composition can form, on a wafer, a uniform thin film that maintains its uniform thickness without causing uneven resin distribution even after being left stand for a certain time and still enables transfer of, and formation of, a fine pattern with good precision from the mold onto the thin film.

The present invention has another object to provide a method for producing a finely patterned substrate using the photocurable composition for nanoimprinting.

The present invention has yet another object to provide a finely patterned substrate produced by the method for producing a finely patterned substrate; and a semiconductor device including the finely patterned substrate.

### Solution to Problem

After intensive investigations to achieve the objects, the inventors of the present invention found that the use of a common, general-purpose solvent in combination with a specific alcohol solvent in a composition including a specific cationically curable compound gives a photocurable composition for nanoimprinting, where the photocurable composition can maintain its uniform thickness without causing uneven resin distribution.

The present invention provides, in an embodiment, a photocurable composition for nanoimprinting including components (A), (B), (C), and (D). The photocurable composition contains the component (C) in a content of 1 to 30 weight percent based on the total amount (100 weight percent) of the photocurable composition. The component (A) is a cationically curable compound represented by Formula (1). The component (B) is a cationic photoinitiator. The component (C) is a hydroxy-containing solvent having a boiling point of 100° C. to 210° C. (at 760 mmHg). The component (D) is a solvent that is devoid of hydroxy, has a boiling point of 140° C. to 210° C. (at 760 mmHg), and has monomer solubility in terms of solubility parameter of 8.0 to 10.0 (cal/cm³)^{1/2}. Formula (1) is expressed as follows:

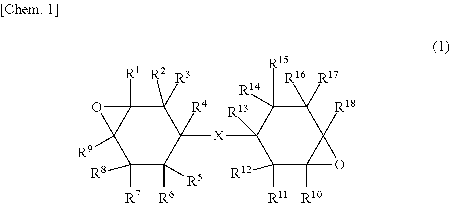

where R¹ to R¹⁸ are, identically or differently, selected from hydrogen, halogen, a hydrocarbon group optionally containing oxygen or halogen, and optionally substituted alkoxy; and X is selected from a single bond and a linkage group.

The photocurable composition for nanoimprinting may further include a compound containing a cationically curable functional group and at least one of an aromatic ring and an aliphatic ring (with the exceptions of compounds corresponding to the component (A)).

The photocurable composition for nanoimprinting may further include a silicone surface conditioner or a hydrocarbon surface conditioner.

The present invention provides, in another embodiment, a method for producing a finely patterned substrate. The method includes subjecting the photocurable composition for nanoimprinting to an imprinting process to give a mask; and etching an inorganic substrate using the mask.

The present invention also provides, in yet another embodiment, a finely patterned substrate obtained by the method for producing a finely patterned substrate.

In addition and advantageously, the present invention provides a semiconductor device including the finely patterned substrate.

Specifically, the present invention relates to followings.

(1) The present invention relates to a photocurable composition for nanoimprinting, where the photocurable composition includes the components (A), (B), (C), and (D). The photocurable composition contains the component (C) in a content of 1 to 30 weight percent based on the total amount (100 weight percent) of the photocurable composition.

(2) The photocurable composition for nanoimprinting according to (1) may further include a compound containing a cationically curable functional group and at least one of an aromatic ring and an aliphatic ring (with the exceptions of compounds corresponding to the component (A)).

(3) In the photocurable composition for nanoimprinting according to (2), the compound containing a cationically curable functional group and at least one of an aromatic ring and an aliphatic ring (with the exceptions of compounds corresponding to the component (A)) may be an oxetane.

(4) The photocurable composition for nanoimprinting according to one of (2) and (3) may contain the compound containing a cationically curable functional group and at least one of an aromatic ring and an aliphatic ring in a content of 5 to 60 weight percent based on the total amount (100 weight percent) of the photocurable composition.

(5) The photocurable composition for nanoimprinting according to any one of (1) to (4) may further include a silicone surface conditioner or a hydrocarbon surface conditioner.

(6) In the photocurable composition for nanoimprinting according to any one of (1) to (5), the cationically curable compound represented by Formula (1) as the component (A) may be selected from compounds represented by Formulae (1-1) to (1-10).

(7) In the photocurable composition for nanoimprinting according to any one of (1) to (6), the cationically curable compound represented by Formula (1) as the component (A) may be (3,4,3′,4′-diepoxy)bicyclohexyl.

(8) The photocurable composition for nanoimprinting according to any one of (1) to (7) may contain the component (A) in a content of 5 to 40 weight percent based on the total amount (100 weight percent) of the photocurable composition.

(9) In the photocurable composition for nanoimprinting according to any one of (1) to (8), the cationic photoinitiator as the component (B) may be at least one compound selected from the group consisting of diazonium salt compounds, iodonium salt compounds, sulfonium salt compounds, phosphonium salt compounds, selenium salt compounds, oxonium salt compounds, ammonium salt compounds, and bromine salt compounds.

(10) The photocurable composition for nanoimprinting according to any one of (1) to (9) may contain the component (B) in a content of 0.1 to 2.0 weight percent based on the total amount (100 weight percent) of the photocurable composition.

(11) In the photocurable composition for nanoimprinting according to any one of (1) to (10), the component (C) may be at least one solvent selected from 3-methoxybutanol and methoxypropanol.

(12) The photocurable composition for nanoimprinting according to any one of (1) to (11) contains the component (C) in a content of 1 to 30 weight percent based on the total amount (100 weight percent) of the photocurable composition.

(13) In the photocurable composition for nanoimprinting according to any one of (1) to (12), the component (D) may be at least one solvent selected from 1-methoxy-2-propyl acetate and 3-methoxybutyl acetate.

(14) The photocurable composition for nanoimprinting according to any one of (1) to (13) may contain the component (D) in a content of 20 to 90 weight percent based on the total amount (100 weight percent) of the photocurable composition.

(15) The photocurable composition for nanoimprinting according to any one of (1) to (14) may have a ratio (weight ratio) of the component (C) to the component (D) of from 3:95 to 40:60.

(16) The photocurable composition for nanoimprinting according to any one of (5) to (15) may contain the silicone surface conditioner or the hydrocarbon surface conditioner in a content (amount) of 0.01 to 1.0 weight percent based on the total amount (100 weight percent) of the photocurable composition.

(17) The present invention also relates to a method for producing a finely patterned substrate. The method includes subjecting the photocurable composition for nanoimprinting according to any one of (1) to (16) to an imprinting process to give a mask, and etching an inorganic substrate using the mask.

(18) The present invention also relates to a finely patterned substrate obtained by the method according to (17).

(19) The present invention also relates to a semiconductor device including the finely patterned substrate according to (18).

### Advantageous Effects of Invention

The photocurable composition for nanoimprinting according to the present invention has the configuration and can form, on a wafer, a uniform thin film that maintains its uniform thickness without causing uneven resin distribution even after being left stand for a certain time and still enables transfer of, and formation of, a fine pattern with good precision from the mold onto the thin film. Thus, the use of the photocurable composition for nanoimprinting according to the present invention enables transfer of a fine pattern with good precision from the mold and efficiently gives a substrate having a fine pattern (finely patterned substrate).

### DESCRIPTION OF EMBODIMENTS

The photocurable composition for nanoimprinting according to the present invention includes components (A), (B), (C), and (D) below. The photocurable composition contains the component (C) in a content of 1 to 30 weight percent based on the total amount (100 weight percent) of the photocurable composition. The component (A) is a cationically curable compound represented by Formula (1). The component (B) is a cationic photoinitiator. The component (C) is a hydroxy-containing solvent having a boiling point of 100° C. to 210° C. (at 760 mmHg). The component (D) is a solvent that is devoid of hydroxy, has a boiling point of 140° C. to 210° C. (at 760 mmHg), and has monomer solubility in terms of solubility parameter of 8.0 to 10.0 (cal/cm³)^{1/2}. Formula (1) is expressed as follows:

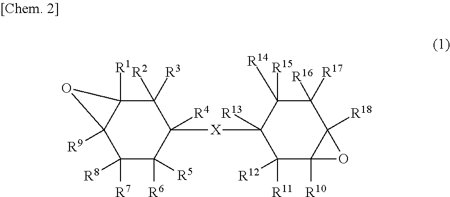

where R¹ to R¹⁸ are, identically or differently, selected from hydrogen, halogen, a hydrocarbon group optionally containing oxygen or halogen, and optionally substituted alkoxy; and X is selected from a single bond and a linkage group.

Component (A)

The component (A) for use in the present invention is a compound that is represented by Formula (1) and is cationically curable. Formula (1) is expressed as follows:

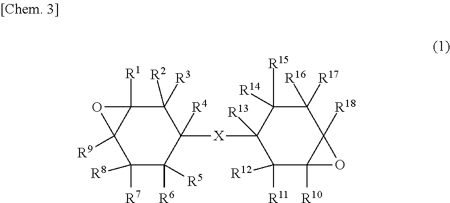

where R¹ to R¹⁸ are, identically or differently, selected from hydrogen, halogen, a hydrocarbon group optionally containing oxygen or halogen, and optionally substituted alkoxy; and X is selected from a single bond and a linkage group.

Non-limiting examples of the halogen as R¹ to R¹⁸ include fluorine, chlorine, bromine, and iodine.

Examples of the hydrocarbon group as R¹ to R¹⁸ include, but are not limited to, aliphatic hydrocarbon groups, alicyclic hydrocarbon groups, aromatic hydrocarbon groups, and groups each including two or more of them bonded to each other.

Non-limiting examples of the aliphatic hydrocarbon groups include C₁-C₂₀ alkyl such as methyl, ethyl, propyl, isopropyl, butyl, hexyl, octyl, isooctyl, decyl, and dodecyl, of which C₁-C₁₀ alkyl is preferred, and C₁-C₄ alkyl is particularly preferred; C₂-C₂₀ alkenyl such as vinyl, allyl, methallyl, 1-propenyl, isopropenyl, 1-butenyl, 2-butenyl, 3-butenyl, 1-pentenyl, 2-pentenyl, 3-pentenyl, 4-pentenyl, and 5-hexenyl, of which C₂-C₁₀ alkenyl is preferred, and C₂-C₄ alkenyl is particularly preferred; and C₂-C₂₀ alkynyl such as ethynyl and propynyl, of which C₂-C₁₀ alkynyl is preferred, and C₂-C₄ alkynyl is particularly preferred.

Non-limiting examples of the alicyclic hydrocarbon groups include C₃-C₁₂ cycloalkyl such as cyclopropyl, cyclobutyl, cyclopentyl, cyclohexyl, and cyclododecyl; C₃-C₁₂ cycloalkenyl such as cyclohexenyl; and C₄-C₁₅ bridged hydrocarbon groups such as bicycloheptyl and bicycloheptenyl.

Non-limiting examples of the aromatic hydrocarbon groups include C₆-C₁₄ aryl such as phenyl and naphthyl, of which C₆-C₁₀ aryl is preferred.

Non-limiting examples of the hydrocarbon group optionally containing oxygen or halogen as R¹ to R¹⁸ include groups corresponding to the hydrocarbon groups, except with an oxygen-containing group or a halogen-containing group replacing at least one hydrogen atom in the hydrocarbon groups. Non-limiting examples of the oxygen-containing group include hydroxy; hydroperoxy; C₁-C₁₀ alkoxy such as methoxy, ethoxy, propoxy, isopropyloxy, butoxy, and isobutyloxy; C₂-C₁₀ alkenyloxy such as allyloxy; tolyloxy, naphthyloxy, and other C₆-C₁₄ aryloxy which may have one or more substituents selected from C₁-C₁₀ alkyl, C₂-C₁₀ alkenyl, halogen, and C₁-C₁₀ alkoxy; C₇-C₁₈ aralkyloxy such as benzyloxy and phenethyloxy; C₁-C₁₀ acyloxy such as acetyloxy, propionyloxy, (meth)acryloyloxy, and benzoyloxy; C₁-C₁₀ alkoxy-carbonyl such as methoxycarbonyl, ethoxycarbonyl, propoxycarbonyl, and butoxycarbonyl; phenoxycarbonyl, tolyloxycarbonyl, naphthyloxycarbonyl, and other C₆-C₁₄ aryloxy-carbonyl which may have one or more substituents selected from C₁-C₁₀ alkyl, C₂-C₁₀ alkenyl, halogen, and C₁-C₁₀ alkoxy; C₇-C₁₈ aralkyloxy-carbonyl such as benzyloxycarbonyl; epoxy-containing groups such as glycidyloxy; oxetanyl-containing groups such as ethyloxetanyloxy; C₁-C₁₀ acyl such as acetyl, propionyl, and benzoyl; isocyanato; sulfo; carbamoyl; oxo; and groups each including two or more of these groups by or without the medium typically of C₁-C₁₀ alkylene. Non-limiting examples of the halogen-containing group include fluoro, chloro, bromo, and iodo.

Non-limiting examples of the optionally substituted alkoxy include halogen, hydroxy, C₁-C₁₀ alkoxy, C₂-C₁₀ alkenyloxy, C₆-C₁₄ aryloxy, C₁-C₁₀ acyloxy, mercapto, C₁-C₁₀ alkylthio, C₂-C₁₀ alkenylthio, C₆-C₁₄ arylthio, C₇-C₁₈ aralkylthio, carboxy, C₁-C₁₀ alkoxy-carbonyl, C₆-C₁₄ aryloxy-carbonyl, C₇-C₁₈ aralkyloxy-carbonyl, amino, mono- or di-C₁-C₁₀ alkyl-amino, C₁-C₁₀ acylamino, epoxy-containing groups, oxetanyl-containing groups, C₁-C₁₀ acyl, oxo, and groups each including two or more of these groups bonded to each other by or without the medium typically of C₁-C₁₀ alkylene.

Among them, R¹ to R¹⁸ are preferably hydrogen.

Examples of the linkage group as X include divalent hydrocarbon groups, carbonyl, ether bond, ester bond, carbonate group, amido, and groups each including two or more of these groups linked to each other. Non-limiting examples of the divalent hydrocarbon groups include C₁-C₁₈ straight or branched chain alkylene and divalent alicyclic hydrocarbon groups. Non-limiting examples of the C₁-C₁₈ straight or branched chain alkylene include methylene, methylmethylene, dimethylmethylene, ethylene, propylene, and trimethylene. Non-limiting examples of the divalent alicyclic hydrocarbon groups include divalent cycloalkylene (including cycloalkydene), such as 1,2-cyclopentylene, 1,3-cyclopentylene, cyclopentylidene, 1,2-cyclohexylene, 1,3-cyclohexylene, 1,4-cyclohexylene, and cyclohexydene.

Typical examples of the cycloaliphatic epoxide represented by Formula (1) include, but are not limited to, compounds represented by Formulae (1-1) to (1-10) below. In Formulae (1-5) and (1-7), p and q each independently represent an integer of 1 to 30. In Formula (1-5), R¹⁹ is, independently in each occurrence, C₁-C₈ alkylene and is exemplified by, but not limited to, straight or branched chain alkylene such as methylene, ethylene, propylene, isopropylene, butylene, isobutylene, s-butylene, pentylene, hexylene, heptylene, and octylene. Among them, preferred is C₁-C₃ straight or branched chain alkylene such as methylene, ethylene, propylene, and isopropylene. In Formulae (1-9) and (1-10), n1 to n6 each independently represent an integer of 1 to 30.

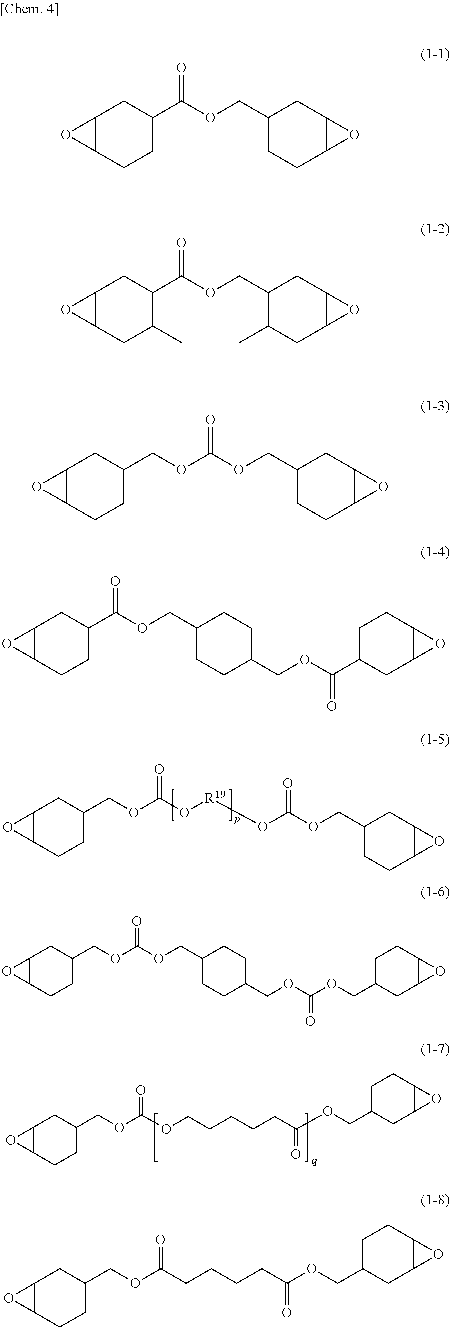

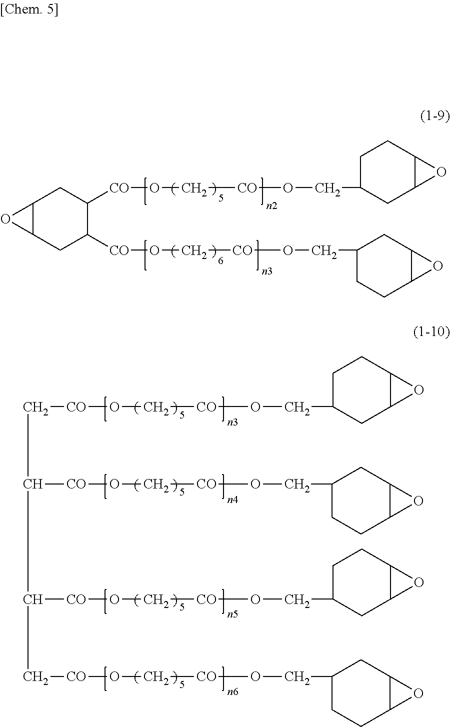

Of the compounds of Formula (1) in which X is a single bond, preferred is (3,4,3′,4′-diepoxy)bicyclohexyl. Of the compounds of Formula (1) in which X is a linkage group, preferred is the compound represented by Formula (1-1), 3,4-epoxycyclohexylmethyl (3,4-epoxy)cyclohexanecarboxylate (e.g., trade name CELLOXIDE 2021P, from Daicel Corporation). The photocurable composition may include each of these compounds alone or in combination as the component (A).

The presence of the component (A) allows the photocurable composition according to the present invention to give a thin film that has excellent curability and shape stability and offers excellent uniformity in film thickness at the resin surface.

The photocurable composition may contain the component (A) in a content not limited, but preferably 5 to 40 weight percent, more preferably 10 to 30 weight percent, and furthermore preferably 10 to 20 weight percent, based on the total amount (100 weight percent) of the photocurable composition. The photocurable composition, when containing the component (A) in a content of 5 to 40 weight percent, may form a thin film that has excellent curability and shape stability and offers excellent uniformity in film thickness at the resin surface.

The proportion of the component (A) to the total amount (100 weight percent) of all cationically curable compounds is not limited, but is preferably 20 to 90 weight percent, more preferably 30 to 80 weight percent, and furthermore preferably 30 to 60 weight percent.

The photocurable composition according to the present invention may further include one or more other cationically curable compounds in addition to the component (A). A non-limiting example of the other cationically curable compounds is a compound containing a cationically curable functional group and including at least one of an aromatic ring and an aliphatic ring. The compound containing a cationically curable functional group and including at least one of an aromatic ring and an aliphatic ring may be copolymerized with the component (A), as needed.

Non-limiting examples of the aromatic ring include benzene, naphthalene, and fluorene rings; and aromatic rings each including two or more of these rings through a single bond or a linkage group. Non-limiting examples of the aliphatic ring include cycloalkane rings such as cyclohexane and cycloheptane rings; and polycyclic rings (bridged rings) such as dicyclopentadiene ring. Non-limiting examples of the cationically curable functional group include cyclic ether groups such as oxetanyl and epoxy; vinyl ether groups; and other electron-donating groups. The compound may contain each of different groups alone or in combination in each category.

Non-limiting examples of the compound containing a cationically curable functional group and including at least one of an aromatic ring and an aliphatic ring include cyclic ether compounds such as oxetanes and epoxides.

The oxetanes are not limited, as long as being compounds containing at least one oxetanyl group as the cationically curable functional group and may be selected from liquids and solids.

Specifically, non-limiting examples of the oxetanes include 3,3-bis(vinyloxymethyl)oxetane, 3-ethyl-3-hydroxymethyloxetane, 3-ethyl-3-(2-ethylhexyloxymethyl)oxetane, 3-ethyl-3-(hydroxymethyl)oxetane, 3-ethyl-3-[(phenoxy)methyl]oxetane, 3-ethyl-3-(hexyloxymethyl)oxetane, 3-ethyl-3-(chloromethyl)oxetane, 3,3-bis(chloromethyl)oxetane, 1,4-bis[(3-ethyl-3-oxetanylmethoxy)methyl]benzene, bis([1-ethyl (3-oxetanyl)]methyl) ether, 4,4′-bis[(3-ethyl-3-oxetanyl)methoxymethyl]bicyclohexyl, 1,4-bis[(3-ethyl-3-oxetanyl)methoxymethyl]cyclohexane, 1,4-bis([(3-ethyl-3-oxetanyl)methoxy]methyl)benzene, 3-ethyl-3([(3-ethyloxetan-3-yl)methoxy]methyl)oxetane, and xylylenebisoxetanes. The oxetanes for use in the present invention may also be selected from commercial products available typically under the trade names OXT221 and OXT121 (each from Toagosei Co., Ltd.); and the trade name OXBP (from Ube Industries, Ltd.). The photocurable composition may include each of different oxetanes alone or in combination.

Among them, preferred is the trade name OXBP (supplied by Ube Industries, Ltd.), which is an oxetane having a biphenyl skeleton. This compound is preferred in points of heat resistance, low moisture absorption, chemical resistance, and compatibility.

The epoxides for use herein are not limited, as long as being compounds containing an epoxy group (in particular, a glycidyl ether group) as the cationically curable functional group, and may be selected from liquids and solids. Non-limiting examples of the epoxides include cycloaliphatic epoxy resins excluding the compounds represented by Formula (1); bisphenol-A epoxy resins; bisphenol-F epoxy resins; bisphenol-S epoxy resins; biphenyl epoxy resins having a biphenyl skeleton; naphthalene epoxy resins; fluorene epoxy resins; dicyclopentadiene epoxy resins having a dicyclopentadiene skeleton; phenol novolac epoxy resins; cresol novolac epoxy resins; modified novolac epoxy resins; and triphenylmethane epoxy resins. The photocurable composition may include each of different epoxides alone or in combination.

Among them, preferred are modified novolac epoxy resins, cycloaliphatic epoxy resins, naphthalene epoxy resins, fluorene epoxy resins, dicyclopentadiene epoxy resins, and biphenyl epoxy resins. These are preferred in points of heat resistance, low moisture absorption, and chemical resistance.

The epoxides may also be selected from commercial products. Non-limiting examples of the commercial products usable herein include modified novolac epoxy resins available typically under the trade name EPICLON N-890 (from DIC Corporation); dicyclopentadiene epoxy resins available typically under the trade name EPICLON HP-7200 (from DIC Corporation); naphthalene epoxy resins available typically under the trade name EPICLON HP-4032 (from DIC Corporation); fluorene epoxy resins available typically under the trade name OGSOL PG-100 (from Osaka Gas Chemicals Co., Ltd.); and biphenyl epoxy resins available typically under the trade name YX4000 (from Mitsubishi Chemical Corporation).

The compound containing a cationically curable functional group and including at least one of an aromatic ring and an aliphatic ring may have a molecular weight not limited. However, the compound preferably has a number-average molecular weight of 300 to 800, for offering better shape transferability.

The photocurable composition may contain the compound containing a cationically curable functional group and including at least one of an aromatic ring and an aliphatic ring in a content not limited, but preferably 5 to 60 weight percent, more preferably 10 to 60 weight percent, and furthermore preferably 30 to 60 weight percent, based on the total amount (100 weight percent) of the photocurable composition. The photocurable composition, when containing the compound in a content of 5 to 60 weight percent, may have better shape transferability.

Component (B)

The cationic photoinitiator serving as the component (B) for use in the present invention is a photoacid generator, which is a compound that generates an acid by photoirradiation and initiates, by the action of the generated acid, the curing reaction of a cationically polymerizable compound contained in the photocurable composition for nanoimprinting. The cationic photoinitiator includes a cationic moiety that absorbs light; and an anionic moiety that acts as a source of the acid.

Non-limiting examples of the cationic photoinitiator for use in the present invention include diazonium salt compounds, iodonium salt compounds, sulfonium salt compounds, phosphonium salt compounds, selenium salt compounds, oxonium salt compounds, ammonium salt compounds, and bromine salt compounds. The photocurable composition may include each of different cationic photoinitiators alone or in combination as the component (B).

Among them, sulfonium salt compounds are preferred for allowing the photocurable composition to give a cured product with excellent curability. Non-limiting examples of the cationic moieties of the sulfonium salt compounds include arylsulfonium ions such as triphenylsulfonium ion, diphenyl[4-(phenylthio)phenyl]sulfonium ion, and tri-p-trisulfonium ion.

Non-limiting examples of the anionic moiety of the cationic photoinitiator include BF₄⁻, B(C₆F₅)₄⁻, PF₆⁻, [(Rf)ₙPF₆₋ₙ]⁻ (where Rf represents alkyl, except with fluorine atoms replacing 80% or more of hydrogen atoms; and n represents an integer of 1 to 5), AsF₆⁻, SbF₆⁻, and pentafluorohydroxyantimonate.

Non-limiting examples of the cationic photoinitiator for use in the present invention include diphenyl[4-(phenylthio)phenyl]sulfonium tetrakis(pentafluorophenyl)borate, diphenyl[4-(phenylthio)phenyl]sulfonium hexafluorophosphate, diphenyl[4-(phenylthio)phenyl]sulfonium tris(pentafluoroethyl)trifluorophosphate, and (1,1′-biphenyl)-4-yl[4-(1,1′-biphenyl)4-ylthiophenyl]phenyl tetrakis(pentafluorophenyl)borate.

The cationic photoinitiator may also be selected from commercial products available typically under the trade names of: CYRACURE UVI-6970, CYRACURE UVI-6974, CYRACURE UVI-6990, and CYRACURE UVI-950 (each from Union Carbide Corporation, U.S.A.); IRGACURE 250, IRGACURE 261, and IRGACURE 264 (each from Ciba Specialty Chemicals Corporation); SP-150, SP-151, SP-170, and OPTOMER SP-171 (each from ADEKA CORPORATION); CG-24-61 (from Ciba Specialty Chemicals Corporation); DAICAT II (from Daicel Corporation); UVAC 1590 and UVAC 1591 (each from DAICEL-CYTEC Company, Ltd.); CI-2064, CI-2639, CI-2624, CI-2481, CI-2734, CI-2855, CI-2823, CI-2758, and CIT-1682 (each from Nippon Soda Co., Ltd.); PI-2074 (from Rhodia, toluyl/cumyliodonium pentafluorophenylborate); FFC509 (from Minnesota Mining & Manufacturing Co.); BBI-102, BBI-101, BBI-103, MPI-103, TPS-103, MDS-103, DTS-103, NAT-103, and NDS-103 (each from Midori Kagaku Co., Ltd.); CD-1010, CD-1011, and CD-1012 (from Sartomer Company, Inc. U.S.A.); and CPI-100P, CPI-101A, and CPI-200K (each from San-Apro Ltd.). The photocurable composition may include each of different cationic photoinitiators alone or in combination as the component (B).

Among them, preferred is [4-(4-biphenylylthio)phenyl]-4-biphenylylphenylsulfonium tris(pentafluoroethyl)trifluorophosphate, which is an initiator containing a fluoroalkyl-fluorophosphate anion.

The photocurable composition may contain the component (B) in a content not limited, but preferably 0.1 to 2.0 weight percent, more preferably 0.1 to 1.0 weight percent, and furthermore preferably 0.2 to 1.0 weight percent, based on the total amount (100 weight percent) of the photocurable composition. The photocurable composition for nanoimprinting, when containing the component (B) in a content of 0.1 to 2.0 weight percent, may have good storage stability and may give a thin film with good curability.

The proportion of the component (B) per 100 parts by weight of the total amount of all cationically curable compounds is not limited, but is preferably 0.5 to 5.0 parts by weight, more preferably 1.0 to 4.0 parts by weight, and furthermore preferably 1.0 to 3.0 parts by weight.

Component (C)

The component (C) for use in the present invention is not limited, as long as being a solvent containing hydroxy and having a boiling point of 100° C. to 210° C. (at 760 mmHg). The component (C) has a boiling point of preferably 110° C. to 180° C., more preferably 120° C. to 170° C., and furthermore preferably 130° C. to 160° C. The component (C) is included in the photocurable composition according to the present invention.

Non-limiting examples of the component (C) include 1-butanol, 2-butanol, isobutyl alcohol, 2-methyl-2-butanol, 3-methoxybutanol, methoxypropanols, 3-methyl-3-methoxybutanol, 1-pentanol, 2-pentanol, 3-pentanol, 3-methyl-1-butanol, 2-methyl-1-butanol, 2,2-dimethyl-1-propanol, 3-methyl-2-butanol, 2-methyl-2-butanol, 1-hexanol, 2-hexanol, 3-hexanol, 2-methyl-1-pentanol, 3-methyl-1-pentanol, 4-methyl-1-pentanol, 2-methyl-2-pentanol, 3-methyl-2-pentanol, 4-methyl-2-pentanol, 2-methyl-3-pentanol, 3-methyl-3-pentanol, 2,2-dimethyl-1-butanol, 2,3-dimethyl-2-butanol, 3,3-dimethyl-2-butanol, 2-ethyl-1-butanol, cyclohexanol, 1-heptanol, 2-heptanol, 3-heptanol, 4-heptanol, 1-octanol, 3-methoxybutanol, methoxypropanols, ethoxypropanols, and 1,3-butanediol. The photocurable composition may include each of these solvents alone or in combination as the component (C).

Among them, the component (C) is preferably selected from 3-methoxybutanol (MB, having a boiling point of 161° C.) and methoxypropanol (MMPG, having a boiling point of 121° C.), for easy control of the solvent volatilization rate.

The photocurable composition according to the present invention includes the component (C) as a solvent. This configuration enables control of the solvent volatilization rate and may eliminate or minimize disadvantages such as local volatilization. This contributes to uniform thickness of the resulting film. In addition, the presence of the alcohol component enables curability control in cationic curing and may less cause swelling of a mold, even when the mold is a silicon mold (nanostamper).

The photocurable composition according to the present invention may contain the component (C) in a content of 1 to 30 weight percent, preferably 3 to 25 weight percent, and more preferably 5 to 20 weight percent, based on the total amount (100 weight percent) of the photocurable composition. The photocurable composition, as containing the component (C) in a content of 1 to 30 weight percent, can have a controlled solvent volatilization rate and may less suffer from disadvantages such as local volatilization.

Component (D)

The component (D) for use in the present invention is not limited, as long as being a solvent that is devoid of hydroxy, has a boiling point of 140° C. to 210° C. (at 760 mmHg), and has monomer solubility. The component (D) may have a boiling point of preferably 145° C. to 195° C., more preferably 147° C. to 190° C., and furthermore preferably 150° C. to 180° C. The component (D) is included in the photocurable composition according to the present invention.

The “solvent having monomer solubility” for use in the present invention refers to a solvent having monomer solubility in terms of solubility parameter of 8.0 to 10.0 (cal/cm³)^{1/2}. The solvent may have a solubility parameter of preferably 8.0 to 9.5 (cal/cm³)^{1/2}, and more preferably 8.0 to 9.0 (cal/cm³)^{1/2}.

The solubility parameter herein is calculated by the method proposed by Fedors et al. and described in literature: Robert F. Fedors, Polymer Engineering & Science, Vol. 14, No. 2, pp. 147-154, February 1974. The solubility parameter is an index indicating that substances having a small difference in solubility parameter are readily miscible with each other (have high dispersibility in each other), but that substances having a large difference in solubility parameter are hardly miscible with each other. All the above-mentioned solubility parameters are values at 25° C.

Non-limiting examples of the component (D) include propylene glycol monoalkyl ether acetates such as propylene glycol monomethyl ether acetate, propylene glycol monoethyl ether acetate, and propylene glycol monobutyl ether acetate; propylene glycol dialkyl ethers such as propylene glycol dimethyl ether, propylene glycol diethyl ether, propylene glycol methyl ethyl ether, and propylene glycol methyl propyl ether; dipropylene glycol dialkyl ethers such as dipropylene glycol methyl propyl ether, dipropylene glycol dimethyl ether, and dipropylene glycol diethyl ether; diacetates such as propylene glycol diacetate and 1,3-butylene glycol diacetate; other acetates such as cyclohexanol acetate, 3-methoxybutyl acetate, and 1-methoxy-2-propyl acetate; ketones such as acetonylacetone, cyclohexanone, 2-heptanone, and 3-heptanone; esters such as diethyl oxalate, methyl 3-methoxypropionate, ethyl 3-methoxypropionate, methyl 3-ethoxypropionate, ethyl 3-ethoxypropionate, ethyl ethoxyacetate, 3-methyl-3-methoxybutyl acetate, 4-methoxybutyl acetate, 3-methyl-3-methoxybutyl propionate, amyl acetate, butyl propionate, propyl butyrate, butyl butyrate, ethyl pyruvate, propyl pyruvate, methyl acetoacetate, ethyl acetoacetate, and ethyl 2-oxobutanoate; aromatic hydrocarbons such as xylenes; and amides such as N,N-dimethylformamide and N,N-dimethylacetamide. The photocurable composition may include each of these solvents alone or in combination as the component (D).

Among them, the component (D) is preferably selected from 1-methoxy-2-propyl acetate (MMPGAC, having a boiling point of 146° C. and a solubility parameter of 8.7 (cal/cm³))^{1/2}) and 3-methoxybutyl acetate (MBA, having a boiling point of 171° C. and a solubility parameter of 8.7 (cal/cm³)^{1/2}). These compounds are preferred for easy control of the solvent volatilization rate and good solubility in the photocurable composition.

The photocurable composition according to the present invention includes, as solvents, the component (C) in combination with the component (D). This configuration offers appropriate dissolution of cationically curable compounds, contributes to control of the solvent volatilization rate, and eliminates or minimizes local volatilization. Thus, the photocurable composition can form a thin film having a uniform thickness.

The photocurable composition may contain the component (D) in a content not limited, but preferably 20 to 90 weight percent, more preferably 30 to 80 weight percent, and furthermore preferably 40 to 70 weight percent, based on the total amount (100 weight percent) of the photocurable composition. The photocurable composition, when containing the component (D) in a content of 20 to 90 weight percent, may allow cationically curable compounds to be dissolved therein sufficiently.

The ratio of the component (C) to the component (D) is not limited, but is preferably from 3:95 to 40:60, and more preferably from 10:90 to 30:70, in terms of weight ratio. The photocurable composition, when containing the component (C) in a ratio within the range, may allow cationically curable compounds to be dissolved sufficiently and may offer a controlled solvent volatilization rate.

Surface Conditioner

Though not limited, the photocurable composition according to the present invention may further include a surface conditioner (flow control agent) as needed. The surface conditioner for use in the present invention is a compound that changes or modifies the surface tension of resin and improves properties such as wettability, leveling properties, slip properties, and defoaming activity (in particular, wettability and leveling properties).

Specifically, examples of the surface conditioner include, but are not limited to, silicone compounds, hydrocarbon compounds, fluorine compounds, and vinyl compounds. The photocurable composition may include each of different surface conditioners alone or in combination.

Exemplary silicone compounds include polydimethylsiloxanes; and modified polydimethylsiloxanes derived from the polydimethylsiloxanes via modification. Non-limiting examples of the modified polydimethylsiloxanes include, of polydimethylsiloxanes, polyether-modified derivatives, alkyl-modified derivatives, polyester-modified derivatives, and aralkyl-modified derivatives. The polyether-modified derivatives are exemplified by polymers corresponding to a polydimethylsiloxane, except for having a structure with a polyether (e.g., polyoxyalkylene) replacing part or all of methyl groups of the polydimethylsiloxane. The alkyl-modified derivatives are exemplified by polymers corresponding to a polydimethylsiloxane, except for having a structure with C2 or higher alkyl replacing part or all of methyl groups of the polydimethylsiloxane. The polyester-modified derivatives are exemplified by polymers corresponding to a polydimethylsiloxane, except for having a structure with a polyester (e.g., an aliphatic polyester, an alicyclic polyester, and/or an aromatic polyester) replacing part or all of methyl groups of the polydimethylsiloxane. The aralkyl-modified derivatives are exemplified by polymers corresponding to a polydimethylsiloxane, except for having a structure with aralkyl replacing part or all of methyl groups of the polydimethylsiloxane.

The silicone compounds may also be selected from commercial products, which are available typically under the trade names BYK-302, BYK-307, BYK-333, BYK-349, BYK-375, and BYK-377 (each from BYK Japan KK); and the trade names POLYFLOW KL-401, POLYFLOW KL-402, POLYFLOW KL-403, and POLYFLOW KL-404 (each from Kyoeisha Chemical Co., Ltd.).

Examples of the hydrocarbon compounds include, but are not limited to, polymers derived from monomer component(s) essentially including an acrylic monomer (acrylic polymers essentially including, as a constitutional unit, a constitutional unit derived from the acrylic monomer). Non-limiting examples of the acrylic monomer include acrylic esters and methacrylic esters; acrylic acid and methacrylic acid; salts of acrylic acid and of methacrylic acid; and acrylamide and methacrylamide. The acrylic esters and methacrylic esters are exemplified by acrylic alkyl esters (and methacrylic alkyl esters); acrylic esters (and methacrylic esters) containing a polar group such as hydroxy, carboxy, and/or amino; and acrylic esters (and methacrylic esters) having a polyester structure (e.g., an aliphatic polyester structure, an alicyclic polyester structure, and an aromatic polyester structure) and/or a polyether structure (e.g., a polyoxyalkylene structure). The acrylic polymers may each be a homopolymer or a copolymer and may be obtained typically by known or common polymerization techniques.

The hydrocarbon compounds may also be selected from commercial products, which are available typically under the trade names BYK-350, BYK-356, BYK-361N, and BYK-3550 (each from BYK Japan KK); and the trade names POLYFLOW No. 75, POLYFLOW No. 77, POLYFLOW No. 90, POLYFLOW No. 95, and POLYFLOW No. 99C (each from Kyoeisha Chemical Co., Ltd.).

The photocurable composition may contain the surface conditioner in a content (amount) not limited, but preferably 0.01 to 1.0 weight percent, and more preferably 0.05 to 0.5 weight percent, based on the total amount (100 weight percent) of the photocurable composition.

Other Components

The photocurable composition according to the present invention may contain any of additives in addition to the above-mentioned components, within ranges not adversely affecting advantageous effects of the present invention. Non-limiting examples of the additives include antifoaming agents, antioxidants, thermal stabilizers, weathering agents, photostabilizers, adhesion imparting agents, and any other common additives. The photocurable composition may contain each of different additives alone or in combination.

Method for Producing Finely Patterned Substrate

The method according to the present invention for producing a finely patterned substrate includes subjecting the photocurable composition for nanoimprinting to an imprinting process to give a mask, and etching an inorganic substrate using the mask. With the method according to the present invention, the finely patterned substrate may be produced typically via steps 1, 2, 3, and 4 as follows.

In the step 1, a thin layer of the photocurable composition for nanoimprinting is applied onto the inorganic substrate to form a coating.

In the step 2, the resulting coating is brought into contact with a mold having a pattern to transfer the pattern to the coating (imprinting process).

In the step 3, the photocurable composition for nanoimprinting is cured via photoirradiation, is then demolded, and yields a thin film to which the pattern shape of the mold has been transferred.

In the step 4, the inorganic substrate is etched using, as a mask, the thin film to which the mold pattern shape has been transferred, to form a fine pattern on the substrate.

Non-limiting examples of the inorganic substrate for use in the step 1 include silicon substrates, sapphire substrates, ceramic substrates, alumina substrates, gallium phosphide substrate, gallium arsenide substrates, indium phosphide substrates, and gallium nitride substrates.

Exemplary techniques for applying the photocurable composition for nanoimprinting onto the inorganic substrate include, but are not limited to, screen process printing, curtain coating, and spraying. In the application, the photocurable composition may be diluted with a diluting solvent to adjust its concentration as needed. Non-limiting examples of the diluting solvent include glycol derivatives such as ethylene glycol monoethyl ether, ethylene glycol monoethyl ether acetate, propylene glycol monomethyl ether, propylene glycol monoethyl ether, propylene glycol monomethyl ether acetate; ketones such as acetone, methyl ethyl ketone, methyl butyl ketone, and cyclohexanone; and esters such as methyl lactate, ethyl lactate, ethyl acetate, and butyl acetate. The resulting coating may have a thickness of typically about 0.1 to about 10 μm, and preferably 0.3 to 3 μm. The thin film, as being obtained using the photocurable composition for nanoimprinting according to the present invention, offers excellent curability.

Non-limiting examples of the mold for use in the step 2 include silicone molds, thermoplastic resin molds, curable resin molds, and metal molds. The mold may be brought into contact with the coating at an embossing pressure of typically about 100 to about 1000 Pa for a contact time of typically about 1 to about 100 seconds. The shape of the mold pattern may be not limited, as long as being a shape that offers better extraction efficiency of light generated in the light-emitting layer, and may be selected typically from trapezoidal, conical, and round shapes.

The light (active energy ray) for use in photoirradiation in the step 3 has only to be such light as to allow the polymerization reaction of the photocurable composition for nanoimprinting and may be any light selected typically from infrared rays, visible light, ultraviolet rays, X rays, electron beams, alpha rays, beta rays, and gamma rays. Among them, ultraviolet rays are preferred for excellent handleability. The irradiation with ultraviolet rays may be performed using sources such as high-pressure mercury lamps, ultra-high pressure mercury lamps, xenon lamps, carbon arc, metal halide lamps, sunlight, LED lamps, and lasers.

The photocurable composition for nanoimprinting according to the present invention has the configuration, is thereby cured at a very high curing rate, and gives a thin film with excellent curability. Photoirradiation conditions may be set as follows. For example, assume that an ultraviolet ray is applied to form a thin film having a thickness of 1 μm. In this case, the ultraviolet cumulative dose is preferably adjusted typically to be about 100 to about 3000 mJ/cm².

The method may further include a postcuring step between the step 3 and the step 4. The presence of the postcuring step may contribute to better shape stability and better etching reproducibility. The postcuring may be performed by the application of heat and/or light. When the postcuring is performed by the application of heat (by heating), the heating is preferably performed typically at about 50° C. to 180° C. for about 0.5 to about 3 hours. When the postcuring is performed by the application of light (photoirradiation), the photoirradiation is preferably performed typically at an irradiation intensity of about 10 to about 100 mW/cm² for about 10 to about 100 seconds.

Exemplary etching techniques in the step 4 include dry etching and wet etching. Among them, the etching in the present invention is preferably selected from dry etching techniques, of which reactive ion etching (RIE) is particularly preferred, for microprocessing with high precision.

The method according to the present invention for producing a finely patterned substrate employs the photocurable composition for nanoimprinting and can form a thin film on the inorganic substrate rapidly by photoirradiation. The thin film obtained in the above manner has a pattern shape transferred from the mold with good precision. The use of this thin film as a mask gives a finely patterned substrate onto which the fine pattern of the mold has been transferred with good precision.

Finely Patterned Substrate

The finely patterned substrate according to the present invention is obtained by the method according to the present invention for producing a finely patterned substrate. The finely patterned substrate according to the present invention has good uniformity in film thickness and good shape transferability and is useful as or in semiconductor materials, diffractive light-condensing films, polarizing films, optical waveguides, and holograms.

Semiconductor Device

The semiconductor device (e.g., LED) according to the present invention includes the finely patterned substrate.

For example, the LED includes an emitter, a lens, wiring, and any other components. The emitter is obtained by allowing a light-emitting layer (GaN layer) to grow on the finely patterned substrate typically via metal-organic phase vapor epitaxy (MOPVE).

The semiconductor device (in particular, LED) according to the present invention includes the finely patterned substrate formed using the photocurable composition for nanoimprinting according to the present invention, offers excellent light-extraction efficiency, and has characteristics such as high brightness, long lifetime, low power consumption, and low heat generation.

### EXAMPLES

The present invention will be illustrated in further detail with reference to several examples below. It should be noted, however, that the examples are by no means intended to limit the scope of the present invention.

### Preparation Example 1

### Preparation of (3,4,3′,4′-diepoxy)bicyclohexyl (a-1)

A dehydration catalyst was prepared by mixing and stirring 70 g (0.68 mol) of 95 weight percent sulfuric acid and 55 g (0.36 mol) of 1,8-diazabicyclo[5.4.0]undecene-7 (DBU).

A 3-liter flask equipped with a stirrer, a thermometer, and a distillation pipe equipped with a dehydration tube and thermally insulated was charged with 1000 g (5.05 mol) of hydrogenated biphenol (i.e., 4,4′-dihydroxybicyclohexyl), 125 g (0.68 mol in terms of sulfuric acid) of the above-prepared dehydration catalyst, and 1500 g of pseudocumene, followed by heating of the flask. Water generation was observed around the time when the internal temperature exceeded 115° C. The temperature was further raised up to the boiling point of pseudocumene (up to an internal temperature of 162° C. to 170° C.), followed by dehydration under normal atmospheric pressure. The by-produced water was distilled out and discharged via the dehydration tube out of the system. The dehydration catalyst was liquid under the reaction conditions and was finely dispersed in the reaction mixture. An approximately stoichiometric amount (180 g) of water was distilled after a lapse of 3 hours, and this was defined as reaction completion. The reaction mixture after reaction completion was subjected to distillation using an Oldershaw distilling column including 10 plates to distill off pseudocumene, was further subjected to distillation at an internal temperature of 137° C. to 140° C. and an internal pressure of 10 Torr (1.33 kPa), and yielded 731 g of bicyclohexyl-3,3′-diene.

Into a reactor, 243 g of the prepared bicyclohexyl-3,3′-diene and 730 g of ethyl acetate were charged. The resulting mixture was combined with 274 g of a 30 weight percent solution (moisture content: 0.41 weight percent) of peracetic acid in ethyl acetate, where the solution was added dropwise over about 3 hours while blowing nitrogen into the gas phase and controlling the temperature in the reaction system at 37.5° C. After the completion of dropwise addition of the peracetic acid solution, the mixture was aged at 40° C. for one hour, and the reaction was completed. Further, the crude mixture obtained upon the reaction completion was washed with water at 30° C., from which low-boiling compounds were removed at 70° C. and 20 mmHg, and yielded 270 g of a cycloaliphatic epoxide. The prepared cycloaliphatic epoxide had an oxirane oxygen content of 15.0 weight percent. The cycloaliphatic epoxide was subjected to ¹H-NMR measurement to find that a peak at a 5 of about 4.5 to about 5 ppm disappeared, where this peak is assigned to an internal double bond, but a peak at a 5 of about 3.1 ppm appeared, where this peak is assigned to an epoxy-derived proton. Thus, the prepared cycloaliphatic epoxide was identified as (3,4,3′,4′-diepoxy)bicyclohexyl.

In examples and comparative examples, components in formulations given in Table 1 below were placed into an eggplant type flask, stirred and mixed with each other at 30° C. until they were dissolved, and yielded uniform photocurable resin compositions for nanoimprinting. Numerical values in Table 1 are in part by weight.

TABLE 1

| | | Example | | | | | | | Comparative Example | | | | |
|---|---|---|---|---|---|---|---|---|---|---|---|---|---|
| | | 1 | 2 | 3 | 4 | 5 | 6 | 7 | 1 | 2 | 3 | 4 | 5 |
| Component (A) | (a-1) | 18 | 18 | 18 | 18 | 24 | 18 | 18 | 18 | 18 | 24 | 18 | 18 |
| Cationically | OXBP | 8 | 8 | 8 | 8 | | 8 | 8 | 8 | 8 | | 8 | 8 |
| curable | N-890 | 13 | 13 | 13 | 13 | | | | 13 | 13 | | 13 | 13 |
| compound | HP-7200 | | | | | 15 | | | | | 15 | | |
| | HP-4032 | | | | | | 13 | | | | | | |
| | PG-100 | | | | | | | 13 | | | | | |
| Component (B) | (b-1) | 0.8 | 0.8 | 0.8 | 0.8 | 0.8 | 0.8 | 0.8 | 0.8 | 0.8 | 0.8 | 0.8 | 0.8 |
| Component (C) | MB | 5 | 24 | | | 5 | 5 | 5 | 50 | | | 60 | 5 |
| | MMPG | | | 5 | 5 | | | | | | | | |
| Component (D) | MMPGAC | 55 | 36 | 55 | | | 55 | 55 | 10 | 60 | | | |
| | MBA | | | | 55 | 55 | | | | | 60 | | |
| Solvent | BA | | | | | | | | | | | | 55 |
| Surface | BYK-350 | 0.2 | 0.2 | 0.2 | | | 0.2 | | 0.2 | 0.2 | 0.2 | 0.2 | 0.2 |
| conditioner | BYK-UV 3510 | | | | 0.2 | 0.2 | | 0.2 | | | | | |

The abbreviations in Table 1 will be described below.

(a-1): Compound Prepared in Production Example 1 ((3,4,3′,4′-diepoxy)bicyclohexyl);

OXBP: Oxetane having a biphenyl skeleton (trade name OXBP, supplied by Ube Industries, Ltd.)

N-890: Modified novolac epoxy resin (trade name EPICLON N-890, supplied by DIC Corporation)

HP-7200: Dicyclopentadiene epoxy resin (trade name EPICLON HP-7200, supplied by DIC Corporation)

HP-4032: Naphthalene epoxy resin (trade name EPICLON HP-4032, supplied by DIC Corporation)

PG-100: Fluorene epoxy resin (trade name OGSOL PG-100, supplied by Osaka Gas Chemicals Co., Ltd.)

(b-1): 50% Dilute solution of an initiator containing an fluoroalkyl-fluorophosphate anion with propylene carbonate, where the initiator is [4-(4-biphenylylthio)phenyl]-4-biphenylylphenylsulfonium tris(pentafluoroethyl)trifluorophosphate,

MB: 3-Methoxybutanol (trade name MB, supplied by Daicel Corporation, having a boiling point of 161° C. and a solubility parameter of 10.9 (cal/cm³)^{1/2})

MMPG: Methoxypropanol (trade name MMPG, supplied by Daicel Corporation, having a boiling point of 121° C. and a solubility parameter of 10.2 (cal/cm³)^{1/2})

MMPGAC: 1-Methoxy-2-propyl acetate (trade name MMPGAC, supplied by Daicel Corporation, having a boiling point of 146° C. and a solubility parameter of 8.7 (cal/cm³)^{1/2})

MBA: 3-Methoxybutyl acetate (trade name MBA, supplied by Daicel Corporation, having a boiling point of 171° C. and a solubility parameter of 8.7 (cal/cm³)^{1/2})

BA: Butyl acetate (trade name BA, supplied by Daicel Corporation, having a boiling point of 126° C. and a solubility parameter of 8.7 (cal/cm³)^{1/2})

BYK-350: Acrylic copolymer (trade name BYK-350, supplied by BYK Japan KK)

BYK-UV 3510: Trade name BYK-UV 3510, supplied by BYK Japan KK, a mixture of a polyether-modified polydimerylsiloxane and a polyether

Evaluations

Results of evaluation points (1) to (5) below are given in Table 2.

(1) Resin Composition Appearance

About 5 mL of each of the photocurable compositions for nanoimprinting as presented in Table 1 were drawn into a transparent 10-mL glass bottle, and whether the composition included a foreign substance and whether the composition as a liquid was cloudy were determined.

(2) Viscosity Measurement

The viscosity (mPa·s) of each of the photocurable compositions for nanoimprinting prepared in the examples and comparative examples was measured using a cone-and-plate viscometer (E-type viscometer) (trade name TVE-25H, supplied by Toki Sangyo Co., Ltd.). About 1.1 mL of each sample were taken and subjected to measurement at a preset temperature of 23° C. in a preset measurement range of “H” at a number of revolutions of 100 rpm. Three minutes into the measurement, the indicated value was read and defined as the viscosity.

(3) Curability Evaluation

Each of the diluted solutions prepared in the examples and comparative examples was applied onto a silicon wafer using a spin coater at a number of revolutions of 500 rpm for 10 seconds and then at a number of revolutions of 3000 rpm for 20 seconds and yielded a coating having a thickness of 1 μm. A polydimethylsiloxane mold (having a pattern with a ratio of height to width (i.e., aspect ratio) of 2:1) was pressed onto and brought into contact with the obtained coating at 200 Pa, and under this condition, the coating was irradiated with an ultraviolet ray at a light quantity of 1000 mJ/cm² using an ultraviolet irradiator (UV or UV-LED irradiator) for 60 seconds, then demolded, and yielded a thin film on which the pattern of the polydimethylsiloxane mold had been imprinted.

The obtained thin film was immersed in acetone at 25° C. for 5 seconds, and the resulting thin film was visually observed, and the curability was evaluated based on the observation according to criteria as follows.

Criteria

Good: The pattern shape was maintained without loosing alignment

Fair: Part of the pattern was dissolved in acetone to leave the resin remained white on the substrate, and a pattern intrusion was observed.

Poor: The pattern was fully lost

(4) Shape Stability Evaluation

The height to width ratio (i.e., aspect ratio) of the pattern was measured on the thin film obtained in the curability evaluation (3), onto which the pattern of the silicone mold had been imprinted, and the shape stability was evaluated according to criteria as follows.

Criteria

Good: Sample had an aspect ratio of 2:1 to 1.9:1

Fair: Sample had an aspect ratio of from 1.5:1 to less than 1.9:1

Poor: Sample had an aspect ratio of less than 1.5:1, or sample suffered from pattern deformation

(5) Surface Uniformity Evaluation (Early Stage)

Each of the photocurable compositions for nanoimprinting prepared in the examples and comparative examples was applied onto a silicon wafer using a spin coater at a number of revolutions as given in the table and yielded a coating having a thickness of 1 μm. The obtained coating was irradiated with an ultraviolet ray at a light quantity of 1000 mJ/cm² using an ultraviolet irradiator (UV or UV-LED irradiator) and yielded a thin film.

The thickness of the obtained thin film was measured using a profiler (trade name T-4000, supplied by Kosaka Laboratory Ltd.), the difference (T₁-T₂) between the central part thickness (T₁) and the outermost periphery thickness (T₂) was determined and defined as a thickness difference, based on which the surface uniformity was evaluated according to criteria as follows.

Criteria

Good: Sample had a thickness difference (T₁-T₂) of 0.020 μm or less

Fair: Sample had a thickness difference (T₁-T₂) of from greater than 0.020 μm to 0.050 μm

Poor: Sample had a thickness difference (T₁-T₂) greater than 0.050 μm

(6) Surface Uniformity Evaluation (after Retention)

Each of the photocurable compositions for nanoimprinting prepared in the examples and comparative examples was applied onto a silicon wafer using a spin coater at a number of revolutions as given in the table and yielded a coating having a thickness of 1 μm. The coating was left stand at an ambient temperature of 23° C. and relative humidity of 50% for one hour, the resulting coating was irradiated with an ultraviolet ray at a light quantity of 1000 mJ/cm² using an ultraviolet irradiator (UV or UV-LED irradiator), and yielded a thin film.

The thickness of the obtained thin film was measured using a profiler (trade name T-4000, supplied by Kosaka Laboratory Ltd.), the difference (T₁-T₂) between the central part thickness (T₁) and the outermost periphery thickness (T₂) was determined and defined as a thickness difference, based on which the surface uniformity was evaluated according to criteria as follows.

Criteria

Good: Sample had a thickness difference (T₁-T₂) of 0.020 μm or less

Fair: Sample had a thickness difference (T₁-T₂) of from greater than 0.020 μm to 0.050 μm

Poor: Sample had a thickness difference (T₁-T₂) of greater than 0.050 μm

TABLE 2

| | Example | | | | | | | Comparative Example | | | | |
|---|---|---|---|---|---|---|---|---|---|---|---|---|
| | 1 | 2 | 3 | 4 | 5 | 6 | 7 | 1 | 2 | 3 | 4 | 5 |
| Appearance | No | No | No | No | No | No | No | No | No | No | No | No |
| of resin | foreign | foreign | foreign | foreign | foreign | foreign | foreign | foreign | foreign | foreign | foreign | foreign |
| composition | sub- | sub- | sub- | sub- | sub- | sub- | sub- | sub- | sub- | sub- | sub- | sub- |
| | stance | stance | stance | stance | stance | stance | stance | stance | stance | stance | stance | stance |
| Viscosity | 5.9 | 6.7 | 6.0 | 6.0 | 4.9 | 5.3 | 5.2 | 10.0 | 5.2 | 4.7 | 6.9 | 5.6 |
| (mPa · · s) | | | | | | | | | | | | |
| Curability | Good | Good | Good | Good | Fair | Good | Good | Fair | Good | Fair | Fair | Good |
| Shape | Good | Good | Good | Good | Good | Good | Good | Poor | Good | Fair | Poor | Poor |
| stability | | | | | | | | | | | | |
| Surface | Good | Good | Good | Good | Good | Good | Good | Fair | Good | Fair | Good | Poor |
| uniformity | | | | | | | | | | | | |
| (early stage) | | | | | | | | | | | | |
| Surface | Good | Good | Good | Good | Good | Good | Good | Fair | Poor | Poor | Good | Poor |
| uniformity | | | | | | | | | | | | |
| (after | | | | | | | | | | | | |
| retention) | | | | | | | | | | | | |

### INDUSTRIAL APPLICABILITY

The photocurable composition for nanoimprinting according to the present invention is used typically as or in radiation-sensitive resins, liquid crystal resist materials, coating materials, coating compositions, and adhesives. The radiation-sensitive resins are used as or in materials for lithography using active radiations such as far-ultraviolet rays, electron beams, ion beams, and X rays in semiconductor processes; and for the formation of insulating films, protective films, and any other components to be provided in electronic components such as liquid crystal display devices, integrated circuit devices, and solid-state imagers. The liquid crystal resist materials are used for the formation of liquid crystal display materials such as liquid crystal display photospacers, liquid crystal display rib-forming materials, over coatings, color resists for color filter formation, and TFT insulating films.

1. A photocurable composition for nanoimprinting, comprising components (A), (B), (C), and (D) as follows:
(A) a cationically curable compound represented by Formula (1);
(B) a cationic photoinitiator;
(C) a hydroxy-containing solvent having a boiling point of 100° C. to 210° C. (at 760 mmHg); and
(D) a solvent being devoid of hydroxy, having a boiling point of 140° C. to 210° C. (at 760 mmHg), and having monomer solubility in terms of solubility parameter of 8.0 to 10.0 (cal/cm³)^{1/2},
the photocurable composition comprising the component (C) in a content of 1 to 30 weight percent based on the total amount (100 weight percent) of the photocurable composition, Formula (1) expressed as follows: 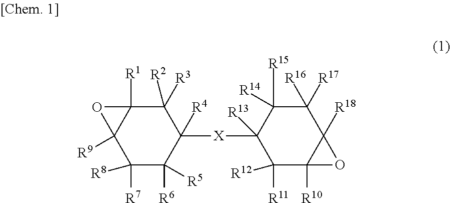
wherein R¹ to R¹⁸ are, identically or differently, selected from hydrogen, halogen, a hydrocarbon group optionally containing oxygen or halogen, and optionally substituted alkoxy; and X is selected from a single bond and a linkage group.

2. The photocurable composition for nanoimprinting according to claim 1, further comprising
a compound comprising:
at least one of an aromatic ring and an aliphatic ring; and
a cationically curable functional group,
with exceptions of compounds corresponding to the component (A).

3. The photocurable composition for nanoimprinting according to claim 1, further comprising
a silicone surface conditioner or a hydrocarbon surface conditioner.

4. A method for producing a finely patterned substrate, the method comprising:
subjecting the photocurable composition for nanoimprinting according to claim 1 to an imprinting process to give a mask; and
etching an inorganic substrate using the mask.

5. A finely patterned substrate obtained by the method according to claim 4.

6. A semiconductor device comprising
the finely patterned substrate according to claim 5.

7. The photocurable composition for nanoimprinting according to claim 2, further comprising
a silicone surface conditioner or a hydrocarbon surface conditioner.

8. A method for producing a finely patterned substrate, the method comprising:
subjecting the photocurable composition for nanoimprinting according to claim 2 to an imprinting process to give a mask; and
etching an inorganic substrate using the mask.

9. A method for producing a finely patterned substrate, the method comprising:
subjecting the photocurable composition for nanoimprinting according to claim 3 to an imprinting process to give a mask; and
etching an inorganic substrate using the mask.

10. A finely patterned substrate obtained by the method according to claim 8.

11. A finely patterned substrate obtained by the method according to claim 9.

12. A semiconductor device comprising the finely patterned substrate according to claim 10.

13. A semiconductor device comprising the finely patterned substrate according to claim 11.
